(19) United States
(12) Patent Application Publication
(10) Pub. No.: US 2026/0304746 A1
(43) Pub. Date: Oct. 1, 2026

(54) SEMICONDUCTOR DEVICE

(71) Applicant: Samsung Electronics Co., Ltd., Suwon-si (KR)

(72) Inventors: Minju Yoon, Suwon-si (KR); Hao Cui, Suwon-si (KR); Ilyoung Yoon, Suwon-si (KR)

(21) Appl. No.: 19/423,196

(22) Filed: Dec. 17, 2025

(30) Foreign Application Priority Data
Mar. 27, 2025 (KR) 10-2025-0039472

(51) Int. Cl. H10B 12/00

(52) U.S. Cl. CPC H10B 12/315; H10B 12/05

(57) ABSTRACT

A semiconductor device includes a bit line extending in a first direction, a word line extending in a second direction intersecting the first direction, a semiconductor pattern disposed adjacent to the word line, a back gate electrode spaced apart from the word line with the semiconductor pattern interposed therebetween, and an isolation insulating pattern spaced apart from the semiconductor pattern with the word line interposed therebetween. A length of the isolation insulating pattern in a third direction is greater than a length of the semiconductor pattern in the third direction, the third direction being perpendicular to the first direction and the second direction.

### CROSS-REFERENCE TO RELATED APPLICATION(S)

This U.S. non-provisional patent application claims priority under 35 U.S.C. §119 to Korean Patent Application No. 10-2025-0039472, filed on Mar. 27, 2025, in the Korean Intellectual Property Office, the entire contents of which are hereby incorporated by reference.

### BACKGROUND

As a semiconductor device is scaled down, it is desired to develop a fabrication technology capable of increasing an integration density, an operation speed, and a production yield of a semiconductor device. Thus, semiconductor devices with vertical channel transistors have been suggested to increase an integration density of a semiconductor device and improve the resistance characteristics and current driving ability of the transistor.

### SUMMARY

Some implementations of the present disclosure provide a semiconductor device with improved electrical characteristic.

According to some implementations of the present disclosure, a semiconductor device may comprise a bit line extending in a first direction, a word line extending in a second direction intersecting the first direction, a semiconductor pattern disposed adjacent to the word line, a back gate electrode spaced apart from the word line with the semiconductor pattern interposed therebetween, and an isolation insulating pattern spaced apart from the semiconductor pattern with the word line interposed therebetween, wherein a length of the isolation insulating pattern in a third direction is greater than that of the semiconductor pattern in the third direction, and the third direction is a direction perpendicular to the first direction and the second direction.

According to some implementations of the present disclosure, a semiconductor device may comprise a bit line extending in a first direction, a word line extending in a second direction intersecting the first direction, a semiconductor pattern disposed adjacent to the word line, a back gate electrode spaced apart from the word line with the semiconductor pattern interposed therebetween; and a first upper insulating layer disposed on the word line, wherein a bottom surface of the first upper insulating layer is recessed toward that of the first upper insulating layer.

According to some implementations of the present disclosure, a semiconductor device may comprise a bit line extending in a first direction, a word line extending in a second direction intersecting the first direction, a semiconductor pattern disposed adjacent to the word line, a gate insulating pattern interposed between the word line and the semiconductor pattern, a back gate electrode spaced apart from the word line and the semiconductor pattern, an isolation spaced apart from the semiconductor pattern with the word line interposed therebetween, a storage node contact disposed on the semiconductor pattern, a data storage pattern disposed on the storage node contact; and a landing pad interposed between the data storage pattern and the storage node contact, wherein a top surface of the isolation insulating pattern is located at a higher level than that of the semiconductor pattern.

### BRIEF DESCRIPTION OF THE DRAWINGS

FIG. 1 is a block diagram of a semiconductor memory device including a semiconductor device according to implementations of the present disclosure.

FIGS. 2 and 3 are perspective views schematically illustrating a semiconductor device according to implementations of the present disclosure.

FIG. 4 is a plan view of a semiconductor device according to implementations of the present disclosure.

FIG. 5 is a cross-sectional view according to A-A′ of FIG. 4.

FIG. 6 is an enlarged sectional view illustrating a portion ‘M’ of FIG. 5.

FIGS. 7 to 14 are cross-sectional views corresponding to A-A′ in FIG. 4 and illustrate an example method of manufacturing a semiconductor device according to implementations of the present disclosure.

### DETAILED DESCRIPTION

Example implementations of the present disclosure will now be described more fully with reference to the accompanying drawings, in which example implementations are shown. Same reference numerals in the drawings denote same elements, and thus their description will be omitted.

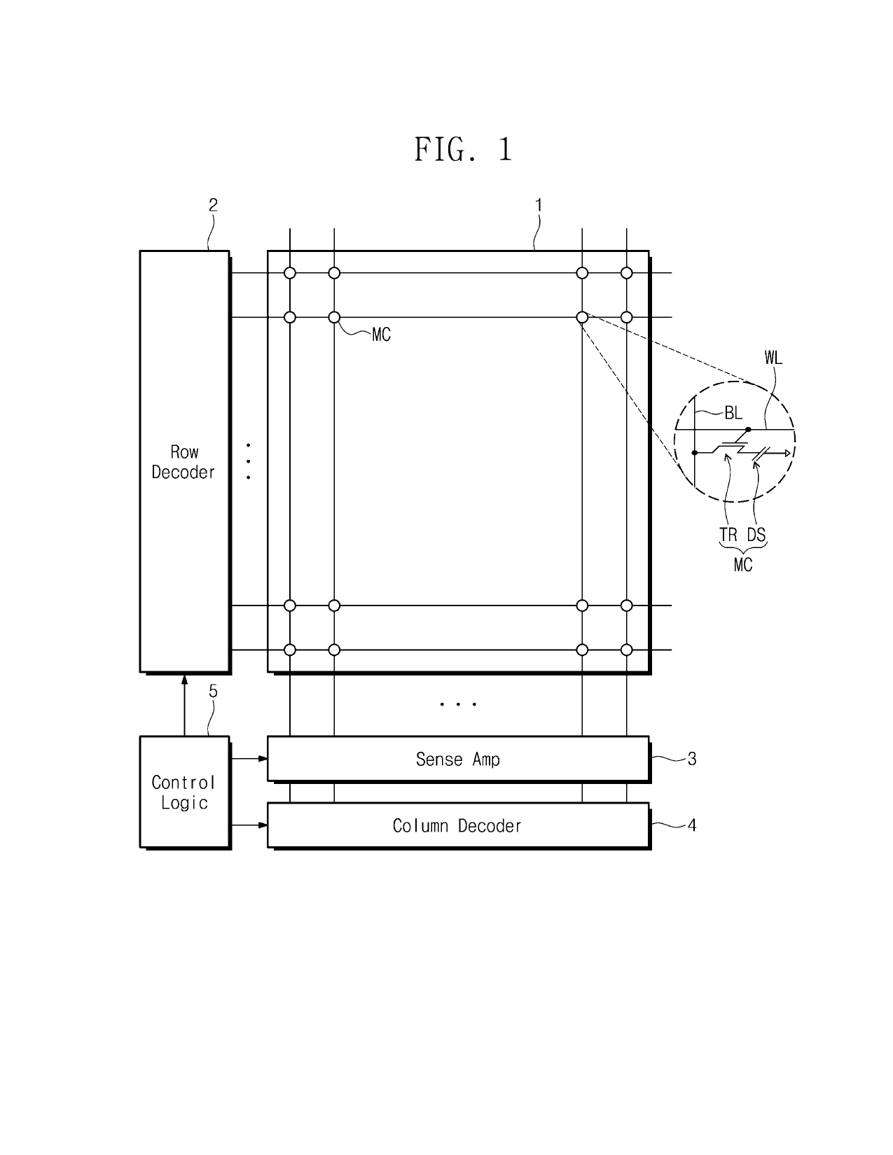

FIG. 1 is a block diagram of a semiconductor memory device including a semiconductor device according to implementations of the present disclosure.

Referring to FIG. 1, a semiconductor device may include a memory cell array 1, a row decoder 2, a sense amplifier 3, a column decoder 4, and a control logic 5.

The memory cell array 1 may include a plurality of memory cells MC arranged two-dimensionally or three-dimensionally. Each of the memory cells MC may be connected between a word line WL and a bit line BL that intersect with each other.

Each of the memory cells MC may include a selection element TR and a data storage element DS. The selection element TR and the data storage element DS may be electrically connected to each other. The selection element TR may be connected to both the word line WL and the bit line BL. In other words, the selection element TR may be provided at a point where the word line WL and the bit line BL intersect with each other.

The selection element TR may include a field-effect transistor. The data storage element DS may include a capacitor, a magnetic tunnel junction pattern, or a variable resistor. For example, a gate terminal of the transistor that is the selection element TR may be connected to the word line WL, and source/drain terminals of the transistor may be connected to the bit line BL and the data storage element DS, respectively.

The row decoder 2 may decode an externally input address to select any one of the word lines WL of the memory cell array 1. The address decoded in the row decoder 2 may be provided to a row driver, and the row driver may provide a predetermined voltage to the selected word line WL and the unselected word lines WL, respectively, in response to control of the control circuits.

The sense amplifier 3 may sense, amplify, and output a voltage difference between the selected bit line BL and the reference bit line according to the address decoded from the column decoder 4.

The column decoder 4 may provide a data transfer path between the sense amplifier 3 and an external device (e.g., a memory controller). The column decoder 4 may decode an externally input address to select any one of the bit lines BL.

The control logic 5 may generate a control signal that controls an operation of writing or reading data into the memory cell array 1.

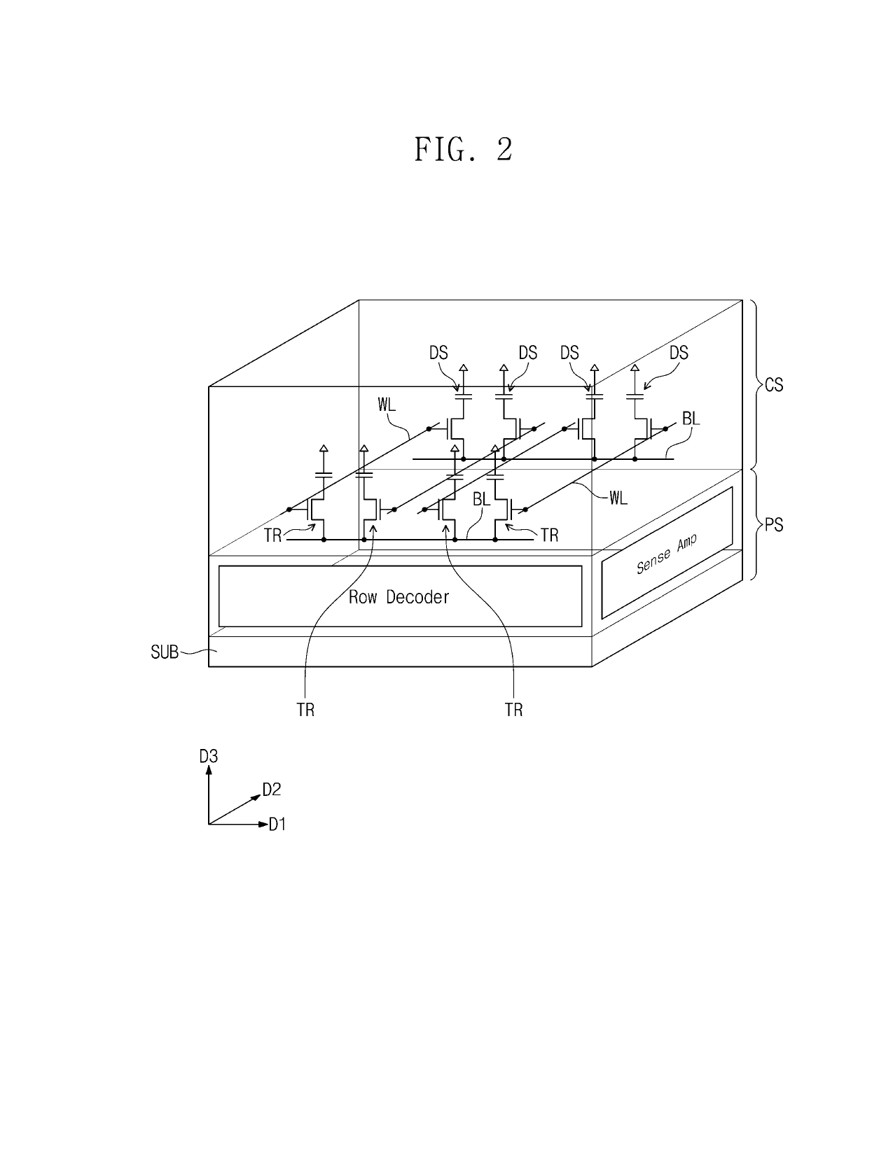

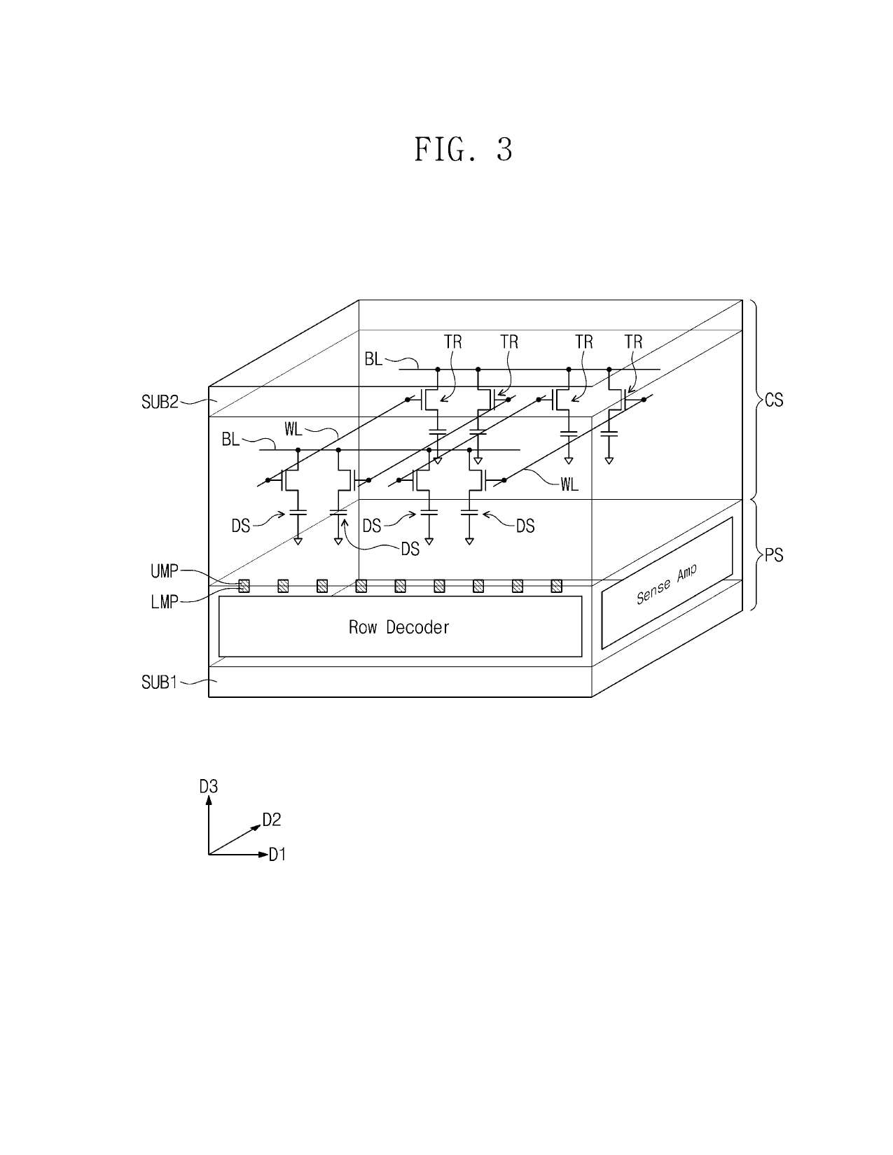

FIGS. 2 and 3 are perspective views schematically illustrating a semiconductor device according to implementations of the present disclosure.

Referring to FIGS. 2 and 3, the semiconductor device may include a peripheral circuit structure PS and a cell structure CS connected to the peripheral circuit structure PS.

The peripheral circuit structure PS may include a core and peripheral circuits formed on a substrate SUB. The core and peripheral circuits may include the row and the column decoders 2, 4, the sense amplifier 3, and the control logic 5 described with reference to FIG. 1.

The cell structure CS may include the memory cell array 1 of FIG. 1 that includes two-dimensionally or three-dimensionally arranged memory cells MC of FIG. 1. Each of the memory cells (MC in FIG. 1) may include the selection element TR and the data storage element DS, as described above.

In some implementations, the selection element TR of each of the memory cells MC of FIG. 1 may include a vertical channel transistor (VCT). The vertical channel transistor may include a channel whose lengthwise direction is a direction perpendicular to the top surface of the substrate SUB. The data storage element DS of each of the memory cells MC in FIG. 1 may include the capacitor.

In the implementations according to FIG. 2, the peripheral circuit structure PS may be provided on the substrate SUB, and the cell structure CS may be provided on the peripheral circuit structure PS.

In the implementations according to FIG. 3, the peripheral circuit structure PS may include a first substrate SUB1, and the cell structure CS may include a second substrate SUB2.

First metal pads LMP may be provided on an uppermost portion of the peripheral circuit structure PS. The first metal pads LMP may be electrically connected to the core and the peripheral circuits 2, 3, 4, and 5 of FIG. 1.

Second metal pads UMP may be provided on a lowermost portion of the cell structure CS. The second metal pads UMP may be electrically connected to the memory cell array 1 (FIG. 1). The second metal pads UMP may be in direct contact with and bonded to the first metal pads LMP of the peripheral circuit structure PS.

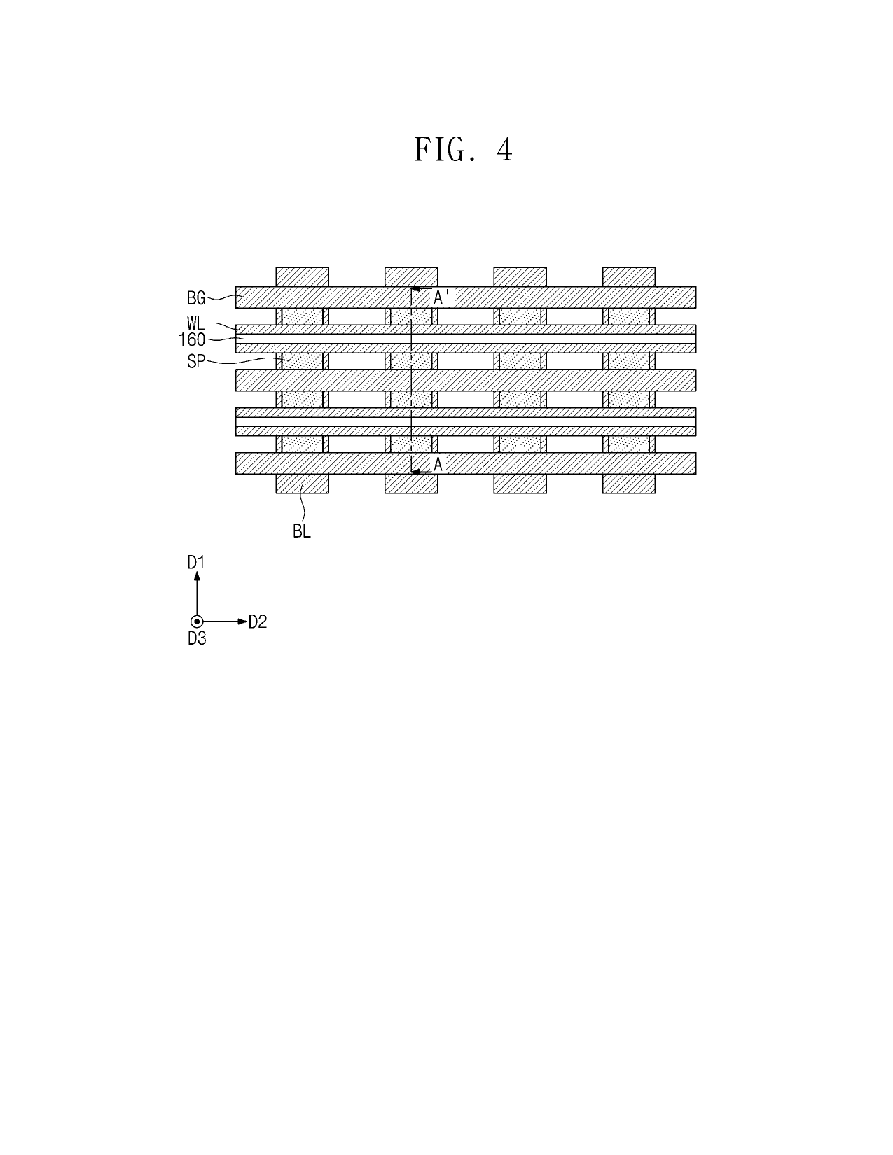

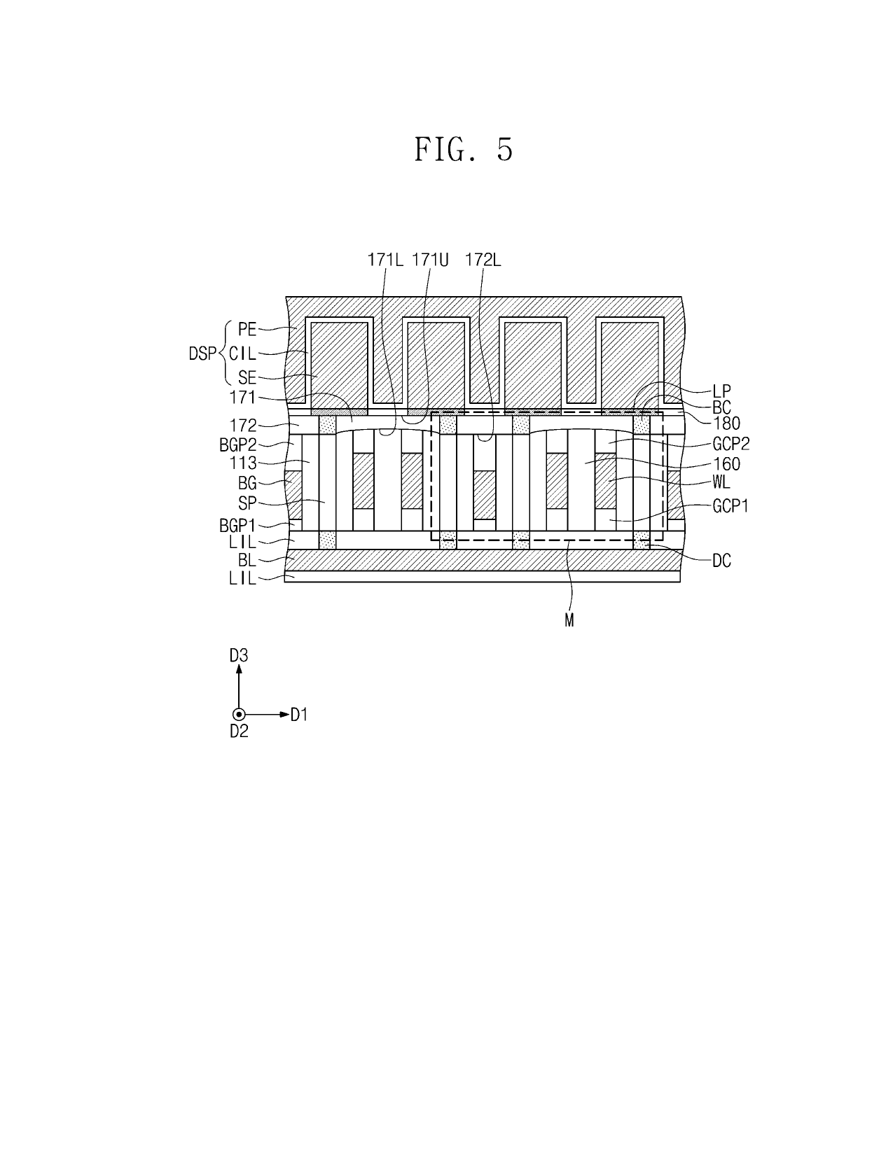

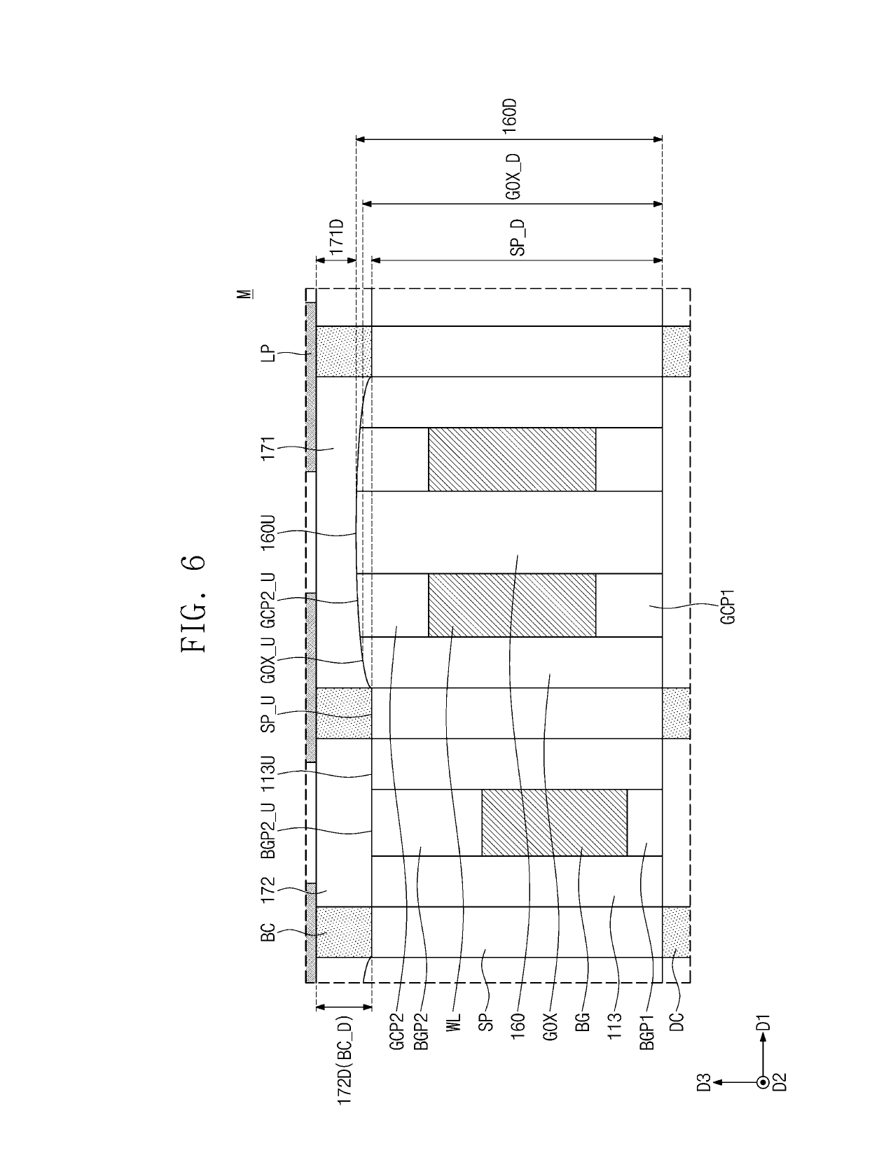

FIG. 4 is a plan view of a semiconductor device according to some implementations of the present disclosure. FIG. 5 is a cross-sectional view according to A-A′ of FIG. 4. FIG. 6 is an enlarged view of M of FIG. 5. For simplicity of description, the same description of the semiconductor device described with reference to FIGS. 1 to 3 is omitted.

Referring to FIGS. 4 to 6, the semiconductor device may include a lower insulating layer LIL. The lower insulating layer LIL may include an insulating material. As an example, the lower insulating layer LIL may be provided under the cell array structure CS described with reference to FIG. 2. In this case, the lower insulating layer LIL may be adjacent to and in contact with the peripheral circuit structure PS described with reference to FIG. 2. In addition, the peripheral circuit structure PS described with reference to FIG. 2 may be interposed between the substrate SUB described with reference to FIG. 2 and the lower insulating layer LIL. Furthermore, the lower insulating layer LIL may include wirings connected to the core and the peripheral circuits of the peripheral circuit structure PS described with reference to FIG. 2.

As another example, the cell array structure (CS in FIG. 2) of the semiconductor device is flipped, so that the lower insulating layer LIL may be provided on an upper portion of the cell array structure CS described with reference to FIG. 3. In this case, the lower insulating layer LIL may be adjacent to and in contact with the second substrate SUB2 described with reference to FIG. 3. In the drawings, a plan view and a cross-sectional view of the cell array structure (CS in FIG. 2) of the semiconductor device in a non-flipped state are shown, and the semiconductor device will be described with reference to these drawings, but the present disclosure is not limited thereto.

The bit line BL may be provided in the lower insulating layer LIL. The bit line BL may extend along a first direction D1 in the lower insulating layer LIL. The bit line BL may include a conductive material. As an example, the bit line BL may include at least one of a doped semiconductor material (e.g., doped silicon, doped germanium, or the like), a metal material (e.g., Ti, Mo, W, Cu, Al, Ta, Ru, Ir, Co, Pt, Ni, or the like or combinations thereof) a metal silicide (e.g., a silicide such as with Ti, Mo, W, Cu, A1, Ta, Ru, Ir, Co, etc. or combinations thereof) or a metal nitride (e.g., a nitride such as with Ti, Mo, W, Cu, Al, Ta, Ru, Ir, Co, etc. or combinations thereof). The bit line BL may be a single layer or a composite layer. A plurality of the bit lines BL may be provided. The bit lines BL may be disposed to be spaced apart from each other along a second direction D2.

A bit line contact DC may be provided in the lower insulating layer LIL. The bit line contact DC may be provided on the bit line BL. The bit line contact DC may be interposed between a semiconductor pattern SP which will be described later and the bit line BL. Accordingly, the bit line BL may be electrically connected to the semiconductor pattern SP through the bit line contact DC. The bit line contact DC may include a conductive material. In one example, the bit line contact DC may include doped silicon. The bit line contact DC may be provided in plurality. The bit line contacts DC may be disposed to be spaced apart from each other along the first direction D1 on the one-bit line BL.

The semiconductor pattern SP may be disposed on the bit line BL. The semiconductor pattern SP may be provided in plurality. The semiconductor patterns SP may be spaced apart from each other in the first and the second directions D1 and D2. A length SP_D of each of the semiconductor patterns SP in a third direction D3 may be substantially the same. Each of the semiconductor patterns SP may be made of a single crystal semiconductor material. Each of the semiconductor patterns SP may include, for example, single crystal silicon.

The word line WL may be disposed on the lower insulating layer LIL and may be disposed adjacent to the semiconductor pattern SP. The word line WL may be disposed on a side surface of the semiconductor pattern SP and may be interposed between the semiconductor patterns SP adjacent to each other in the first direction D1.

The word line WL may be provided in plurality. The word lines WL may extend in the second direction D2 and may be spaced apart from each other in the first direction D1. As an example, a pair of the word lines WL adjacent to each other in the first direction D1 may be interposed between the semiconductor patterns SP adjacent to each other, in the first direction D1.

The word line WL may include, for example, but is not limited to, at least one of doped polysilicon, a metal (e.g., Al, Cu, Ti, Ta, Ru, W, Mo, Pt, Ni, Co, or combinations thereof), a conductive metal nitride (e.g., TiN, TaN, WN, NbN, TiAlN, TiSiN, TaSiN, RuTiN), a conductive metal silicide, or a conductive metal oxide (for example, PtO, RuO₂, IrO₂, SRO (SrRuO₃), BSRO ((Ba,Sr)RuO₃) or CRO (CaRuO3)).

The word line WL may include a single layer or multiple layers of the above-described materials. In some implementations, the word line WL may include a two-dimensional semiconductor material, for example, the two-dimensional semiconductor material may include graphene, carbon nanotubes, or a combination thereof.

A lower gate capping pattern GCP1 may be interposed between the word line WL and the lower insulating layer LIL, and an upper gate capping pattern GCP2 may be disposed on the word line WL. The word line WL may be interposed between the lower gate capping pattern GCP1 and the upper gate capping pattern GCP2.

The lower gate capping pattern GCP1, the word line WL, and the upper gate capping pattern GCP2 may be sequentially stacked along the third direction D3 on a one side of the semiconductor pattern SP. A top surface GCP2_U of the upper gate capping pattern GCP2 may be located at a higher level than a top surface SP_U of the semiconductor pattern SP. The lower gate capping pattern GCP1 and the upper gate capping pattern GCP2 may include an insulating material, and may include, for example, at least one of silicon oxide or silicon nitride. In the present specification, the level may refer to a position spaced apart from the lower insulating layer LIL in the third direction D3.

A gate insulating pattern GOX may be interposed between the word line WL and the semiconductor pattern SP. The gate insulating pattern GOX may be in contact with a side surface of the word line WL and the one side surface of the semiconductor pattern SP. The gate insulating pattern GOX may cover side surfaces of the word line WL, the lower gate capping pattern GCP1, and the upper gate capping pattern GCP2.

A top surface GOX_U of the gate insulating pattern GOX may be located at a higher level than the top surface SP_U of the semiconductor pattern SP and may be located at a lower level than the top surface GCP2_U of the upper gate capping pattern GCP2. A length GOX_D of the gate insulating pattern GOX in the third direction D3 may be greater than the length SP_D of the semiconductor pattern SP in the third direction D3.

The gate insulating pattern GOX may include at least one of silicon oxide, silicon oxynitride, or a high dielectric material having a dielectric constant higher than that of silicon oxide. The high dielectric material may comprise a metal oxide or a metal oxynitride. For example, the high dielectric material as the gate insulating pattern GOX may include at least one of HfO₂, HfSiO, HfSiON, HfTaO, HfTiO, HfZrO, ZrO₂, or Al₂O_{3.}

An isolation insulating pattern 160 may be disposed between the word lines WL adjacent to each other. The isolation insulating pattern 160 may be spaced apart from the semiconductor pattern SP with the word line WL interposed therebetween. A top surface 160U of the isolation insulating pattern 160 may be located at a higher level than the top surface SP_U of the semiconductor pattern SP, the top surface GOX_U of the gate insulating pattern GOX, and the top surface GCP2_U of the upper gate capping pattern GCP2. A length 160D of the isolation insulating pattern 160 in the third direction D3 may be greater than the length SP_D of the semiconductor pattern SP in the third direction D3 and may be greater than the length GOX_D of the gate insulating pattern GOX in the third direction D3. For example, the isolation insulating pattern 160 may comprise at least one of silicon oxide, silicon nitride, silicon oxynitride or a low dielectric material.

A back gate electrode BG may extend across the bit line BL in the second direction D2 on the bit line BL. The back gate electrode BG may be disposed between the semiconductor pattern SP adjacent to each other in the first direction D1.

The back gate electrode BG may be provided in plurality. The back gate electrodes BG may be spaced apart from each other in the first direction D1. In other words, the back gate electrodes BG may be spaced apart from each other in the first direction D1 with the semiconductor pattern SP aligned in the second direction D2 interposed therebetween.

A back gate insulating pattern 113 may be interposed between the back gate electrode BG and a side surface of the semiconductor pattern SP. The back gate insulating pattern 113 may cover a side surface of the back gate electrode BG. The back gate insulating pattern 113 may be provided in plurality. The back gate insulating patterns 113 may extend in the second direction D2 and may be spaced apart from each other in the first direction D1.

A top surface 113U of the back gate insulating pattern 113 may be coplanar with the top surface SP_U of the semiconductor pattern SP. The top surface 113U of the back gate insulating pattern 113 may be located at a lower level than the top surface GOX_U of the gate insulating pattern GOX, the top surface GCP2_U of the upper gate capping pattern GCP2, and the top surface 160U of the isolation insulating pattern 160.

The back gate insulating pattern 113 may include at least one of silicon oxide, silicon oxynitride, or a high dielectric material having a dielectric constant higher than that of silicon oxide. The high dielectric material may comprise a metal oxide or a metal oxynitride. For example, the high dielectric material as the back gate insulating pattern 113 may include at least one of HfO₂, HfSiO, HfSiON, HfTaO, HfTiO, HfZrO, ZrO₂, or Al₂O_{3.}

A lower back gate capping pattern BGP1 may be disposed between the back gate electrode BG and the lower insulating layer LIL, and an upper back gate capping pattern BGP2 may be disposed on the back gate electrode BG. The back gate electrode BG may be interposed between the lower back gate capping pattern BGP1 and the upper back gate capping pattern BGP2. The lower back gate capping pattern BGP1, the back gate electrode BG, and the upper back gate capping pattern BGP2 may be sequentially stacked along the third direction D3 on a side of the semiconductor pattern SP.

A top surface BGP2_U of the upper back gate capping pattern BGP2 may be coplanar with the top surface 113U of the back gate insulating pattern 113 and the top surface SP_U of the semiconductor pattern SP. The upper back gate capping pattern BGP2 may be located at a lower level than the top surface GOX_U of the gate insulating pattern GOX, the top surface GCP2_U of the upper gate capping pattern GCP2, and the top surface 160U of the isolation insulating pattern 160.

The lower back gate capping pattern BGP1 and the upper back gate capping pattern BGP2 may include an insulating material, and may include, for example, at least one of silicon oxide or silicon nitride.

A first upper insulating layer 171 may be disposed on the gate insulating pattern GOX, the word line WL, the upper gate capping pattern GCP2, and the isolation insulating pattern 160. A bottom surface 171L of the first upper insulating layer 171 may be recessed toward the top surface 171U of the first upper insulation layer 171. The bottom surface 171L of the first upper insulating layer 171 may be recessed toward a data storage pattern DSP to be described later.

A length 171D of the first upper insulating layer 171 in the third direction D3 may become smaller as it gets closer to the isolation insulating pattern 160 in the first direction D1. A portion of the first upper insulating layer 171 having a minimum length in the third direction D3 may be provided on the isolation insulating pattern 160.

A second upper insulating layer 172 may be disposed on the back gate electrode BG, the upper back gate capping pattern BGP2, and the back gate insulating pattern 113. A bottom surface 172L of the second upper insulating layer 172 may be located at a lower level than the bottom surface 171L of the first upper insulating layer 171.

A length 172D of the second upper insulating layer 172 in the third direction D3 may be greater than the length 171D of the first upper insulating layer 171 in the third direction D3. The length 172D of the second upper insulating layer 172 in the third direction D3 may be greater than the minimum length of the length of the first upper insulating layer 171 in the third direction D3. The first and second upper insulating layers 171, 172 may include, for example, silicon nitride.

A storage node contact BC may be disposed through the first and second upper insulating layers 171 and 172. The first and second upper insulating layers 171 and 172 may cover side surfaces of the storage node contact BC. The storage node contact BC may be provided in plurality. The storage node contacts BC may be spaced apart from each other in the first direction D1 and the second direction D2.

Each of the storage node contacts BC may be disposed on the semiconductor pattern SP. A length BC_D of the storage node contact BC in the third direction D3 may be greater than the length 171D of the first upper insulating layer 171 in the third direction D3. For example, the length BC_D of the storage node contact BC in the third direction D3 may be substantially the same as the length 172D of the second upper insulating layer 172 in the third direction D3. The storage node contact BC may include, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

An isolation insulating layer 180 and a landing pad LP may be disposed on the first and the second upper insulating layers 171 and 172. From a planar perspective, a plurality of the landing pads LP may be spaced apart from each other in the first and second directions D1 and D2 and may be arranged in various shapes such as a matrix shape, a zigzag shape, a honeycomb shape, and the like. From a planar perspective, each of the landing pads LP may have various shapes such as a circle, an ellipse, a rectangle, a square, a rhombus, and a hexagon.

The landing pads LP may include, for example, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

The data storage pattern DSP may be disposed on the landing pad LP. The data storage pattern DSP may be electrically connected to the semiconductor pattern SP through the landing pad LP.

According to some implementations, the data storage pattern DSP may be a capacitor, and may include a storage electrode SE, a plate electrode PE, and a capacitor dielectric layer CIL interposed therebetween. In this case, the storage electrode SE may contact the landing pad LP.

Alternatively, the data storage pattern DSP may be a variable resistance pattern that may be switched to two resistance states by an electrical pulse applied to the memory element. For example, the data storage pattern DSP may include a phase-change material whose crystal state changes according to the amount of current, perovskite compounds, transition metal oxide, magnetic materials, ferromagnetic materials, or antiferromagnetic materials.

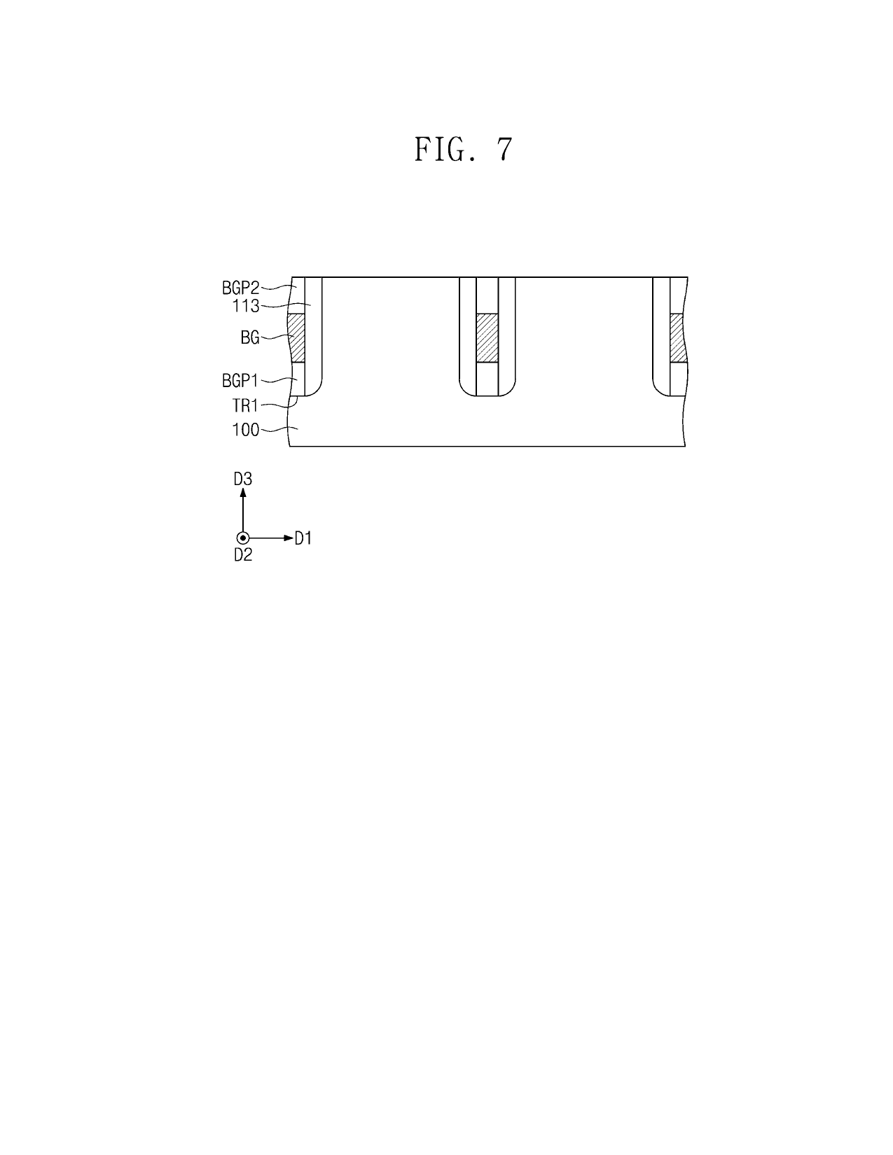

FIGS. 7 to 14 are diagrams illustrating a method of manufacturing a semiconductor device according to implementations of the present disclosure and are cross-sectional views corresponding to A-A′ in FIG. 4. A description the same as the semiconductor device described with reference to FIGS. 1 to 6 will be omitted.

Referring to FIGS. 4 and 7, the back gate insulating pattern 113 may be formed in the semiconductor substrate 100. The semiconductor substrate 100 may be a silicon (e.g., single crystal silicon) substrate. Forming the back gate insulating pattern 113 may include, for example, patterning the semiconductor substrate 100 to form a first trench TR1, depositing an insulating material partially filling the first trench TR1, and removing a portion of the insulating material. The removal of a portion of the insulating material may be performed, for example, by an anisotropic etching process.

The lower back gate capping pattern BGP1 may be formed in the semiconductor substrate 100. Forming the lower back gate capping pattern BGP1 may include, for example, depositing an insulating layer on the back gate insulating pattern 113 to fill the first trench TR1, and recessing the insulating layer.

The back gate electrode BG may be formed on the lower back gate capping pattern BGP1. Forming the back gate electrode BG may include, for example, forming a back gate conductive layer on the lower back gate capping pattern BGP1, and recessing the back gate conductive layer.

The upper back gate capping pattern BGP2 may be formed on the back gate electrode BG. Forming the upper back gate capping pattern BGP2 may include, for example, filling the remainder of the first trench TR1 with the upper back gate capping layer, and planarizing until a top surface of the semiconductor substrate 100 is exposed.

According to implementations of the present disclosure, a bulk silicon substrate (e.g., a single crystal silicon substrate) may be used instead of a Silicon On Insulator (SOI) substrate to fabricate a semiconductor device. Therefore, manufacturing cost of a semiconductor device may be reduced.

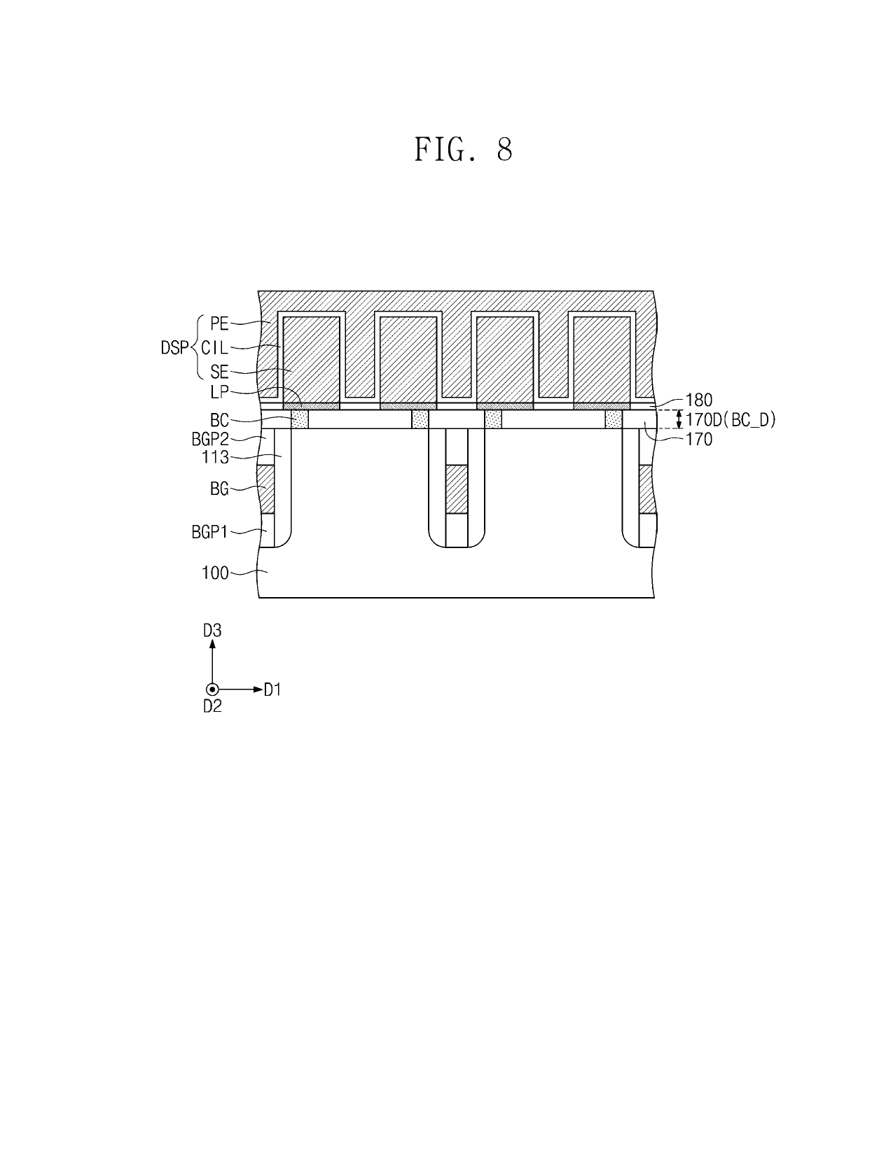

Referring to FIGS. 4 and 8, an upper insulating layer 170 may be formed on the semiconductor substrate 100. The upper insulating layer 170 may cover the upper back gate capping pattern BGP2 and the back gate insulating pattern 113. The upper insulating layer 170 may include, for example, silicon nitride.

The storage node contact BC may be formed through the upper insulating layer 170. The length BC_D of the storage node contact BC in the third direction D3 may be substantially the same as a length 170D of the upper insulating layer 170 in the third direction D3. The storage node contact BC may be in contact with the semiconductor substrate 100. At least a portion of the storage node contact BC may not overlap the back gate electrode BG in the third direction D3.

Forming the storage node contact BC may include etching the upper insulating layer 170 to form a hole exposing a top surface of the semiconductor substrate 100, depositing a conductive layer filling the hole, and planarizing the conductive layer until a top surface of the upper insulating layer 170 is exposed.

The isolation insulating layer 180 may be formed on the upper insulating layer 170. The landing pad LP connected to the storage node contact BC may be formed through the isolation insulating layer 180. Forming the landing pad LP may include, for example, etching the isolation insulating layer 180 to form a hole exposing the storage node contact BC, depositing a conductive layer filling the hole and planarizing the conductive layer so that a top surface of the isolation insulating layer 180 is exposed.

The data storage pattern DSP connected to the landing pad LP may be formed on the landing pad LP. Specifically, the storage electrode SE may be formed on the landing pad LP, and the capacitor dielectric layer CIL conformally covering the storage electrode SE may be formed. Then, the plate electrode PE may be formed on the capacitor dielectric layer CIL.

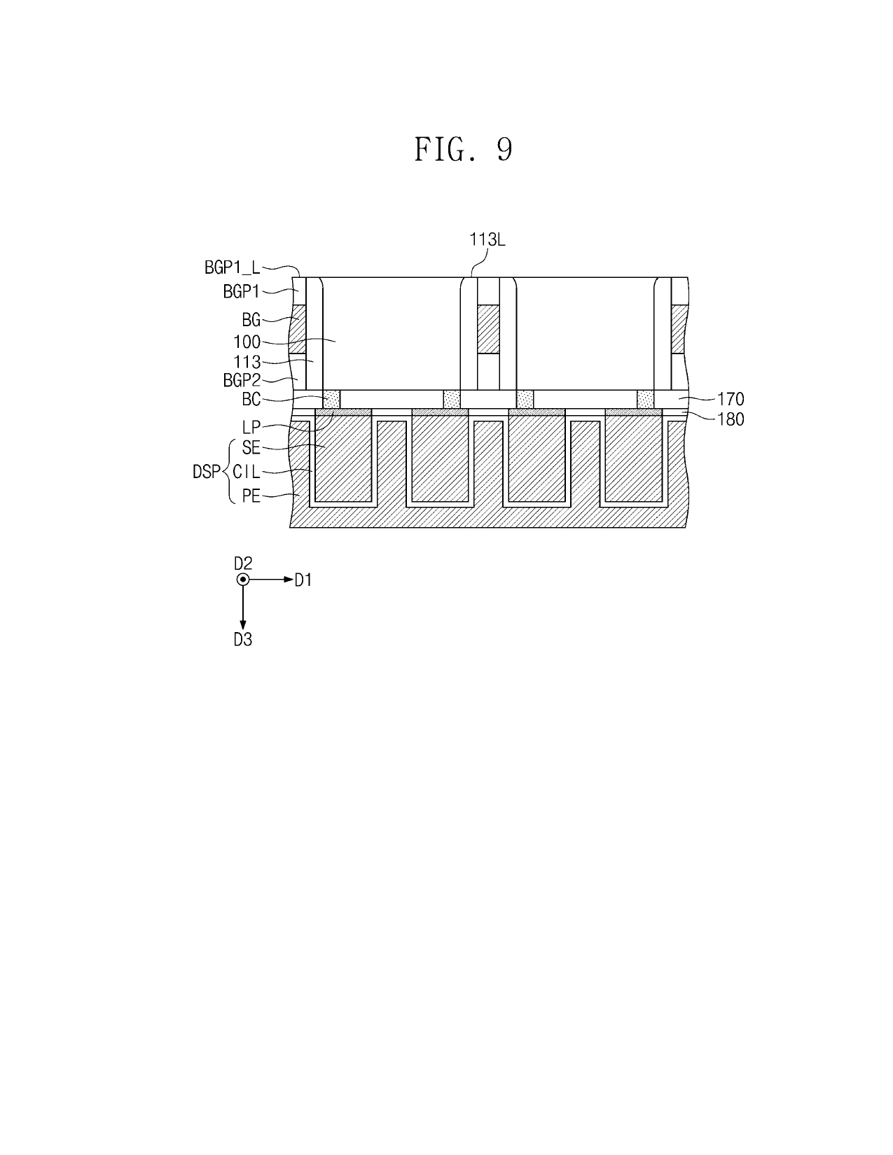

Referring to FIGS. 4 and 9, after the data storage pattern DSP is formed, the semiconductor device being manufactured may be flipped over. That is, the data storage pattern DSP may be inverted downward.

A planarization process may then proceed. The planarization process of the semiconductor substrate 100 may proceed until a bottom surface BGP1_L of the lower back gate capping pattern BGP1 and a bottom surface 113L of the back gate insulating pattern 113 are exposed.

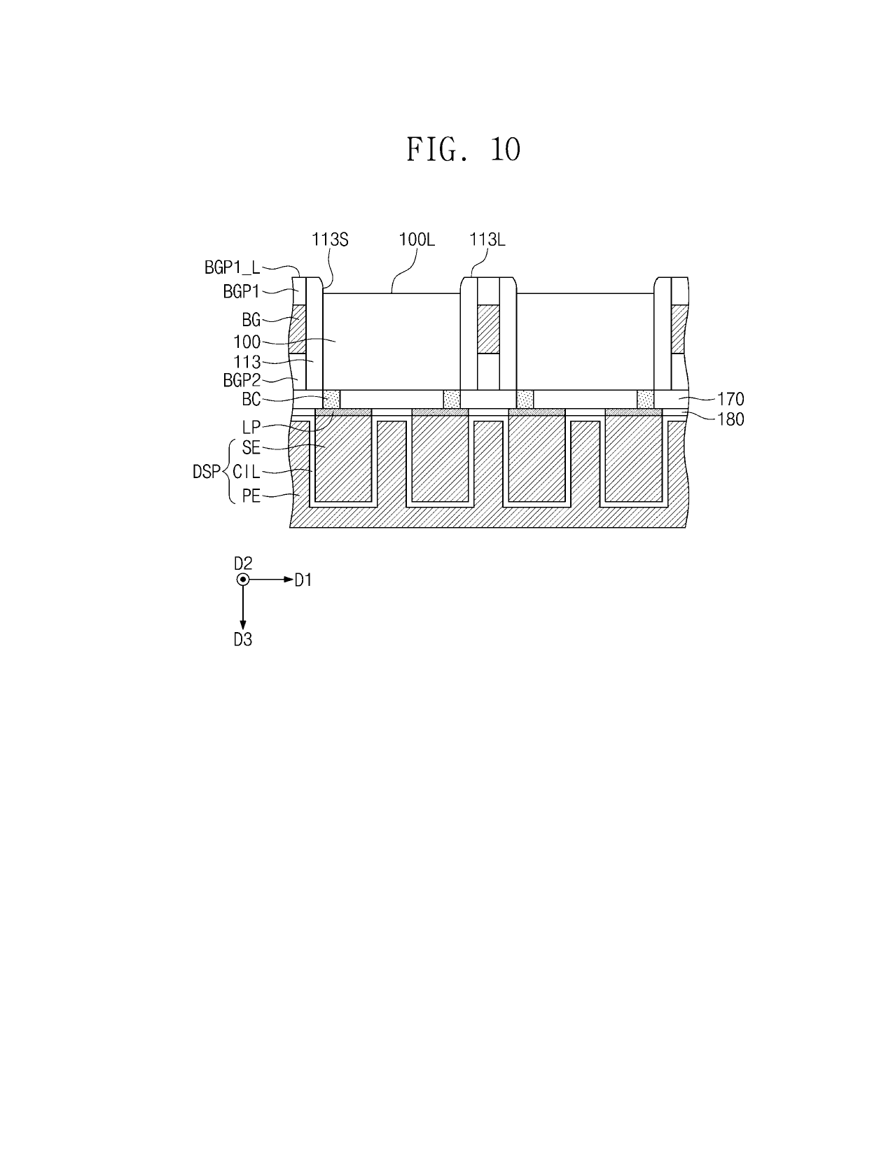

Referring to FIGS. 4 and 10, a bottom surface 100L of the semiconductor substrate 100 may be recessed toward the data storage pattern DSP. A side surface 113S of the back gate insulating pattern 113 may be exposed by the recess process. The bottom surface 100L of the semiconductor substrate 100 may be located at a lower level than a bottom surface 113L of the back gate insulation pattern 113 and the bottom surface BGP1_L of the lower back gate capping pattern BGP1. Recessing the semiconductor substrate 100 may include, for example, selectively etching the semiconductor substrate 100.

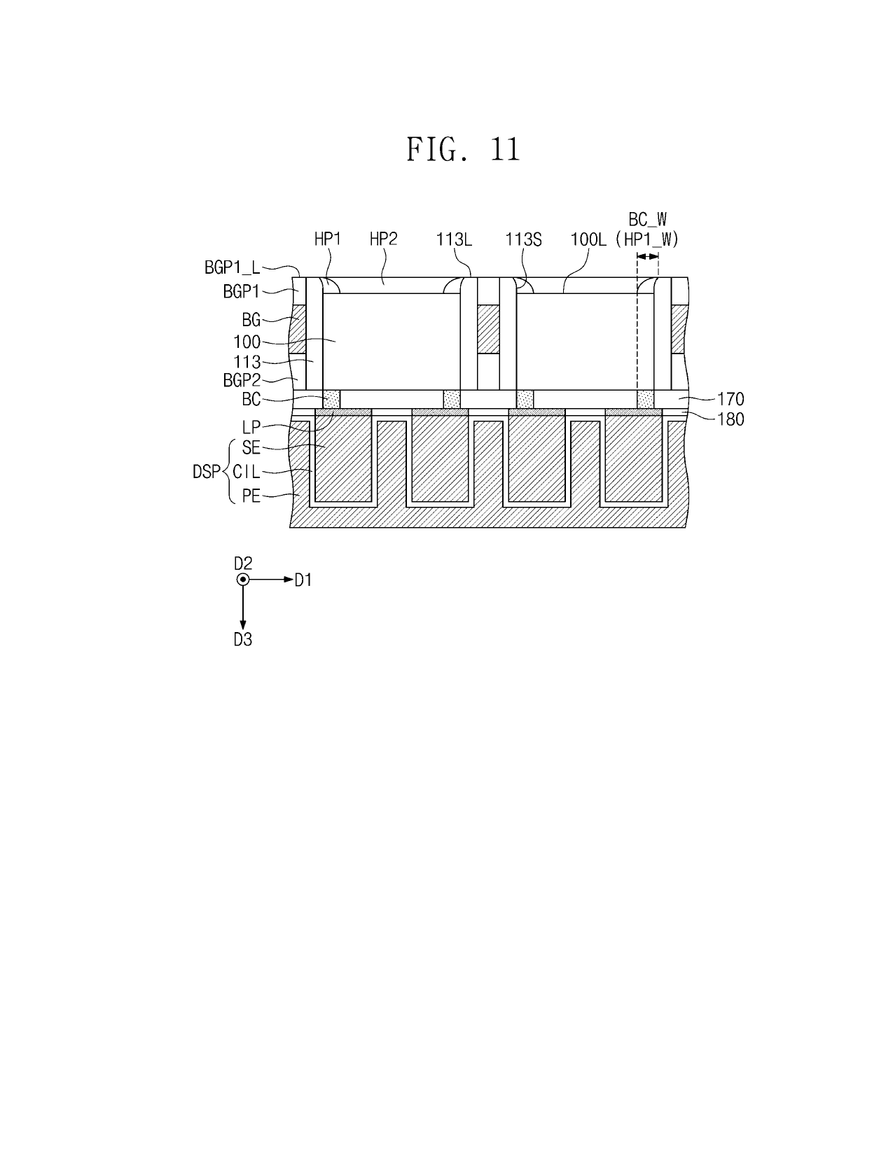

Referring to FIGS. 4 and 11, a first hard mask pattern HP1 may be formed on the bottom surface 100L of the recessed semiconductor substrate 100. A width HP1_W of the first hard mask pattern HP1 in the first direction D1 may correspond to a width BC_W of the storage node contact BC in the first direction D1. The width HP1_W of the first hard mask pattern HP1 in the first direction D1 may be substantially the same as the width BC_W of the storage node contact BC in the first direction D1. The width HP1_W of the first hard mask pattern HP1 in the first direction D1 may mean, for example, the width HP1_ W of the first hard mask pattern HP1 in the first direction D1 on the semiconductor substrate 100.

The first hard mask pattern HP1 may be formed on the side surface 113S of the exposed back gate insulating pattern 113. The first hard mask pattern HP1 may extend in the second direction D2 along the back gate insulating pattern 113. The first hard mask pattern HP1 may be provided in plurality. The first hard mask patterns HP1 may be spaced apart from each other along the first direction D1.

The first hard mask pattern HP1 may include an insulating material, for example, may include an oxide. Forming the first hard mask pattern HP1 may include, for example, depositing an oxide layer through a deposition method and anisotropically etching the oxide layer.

A second hard mask pattern HP2 may be formed on the bottom surface 100L of the recessed semiconductor substrate 100 and the first hard mask pattern HP1. The second hard mask pattern HP2 may extend in the first direction D1. A plurality of the second hard mask patterns HP2 may be spaced apart from each other along the second direction D2.

Forming the second hard mask pattern HP2 may include depositing a polymer layer and planarizing the polymer layer until the bottom surface BGP1_L of the lower back gate capping pattern BGP1 exposed.

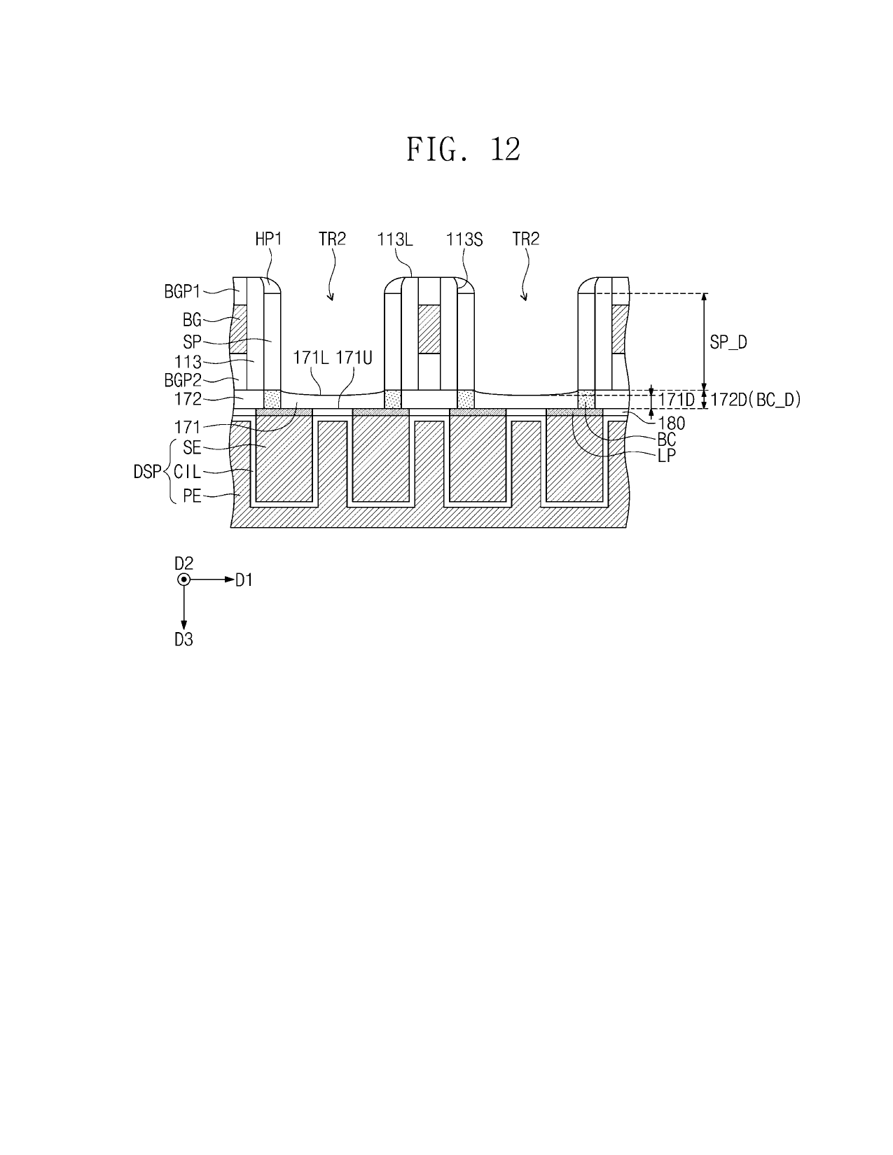

Referring to FIGS. 4 and 12, the semiconductor pattern SP may be formed on a side surface of the back gate insulating pattern 113 and may be formed between the first hard mask pattern HP1 and the storage node contact BC. The semiconductor pattern SP may be formed on the storage node contact BC. The plurality of the semiconductor patterns SP may be formed. The length SP_D of each of the semiconductor patterns SP in the third direction D3 may be substantially the same.

Forming the semiconductor pattern SP may include etching the semiconductor substrate 100 with the second hard mask pattern HP2 as an etching mask, removing the second hard mask patterns HP2, and etching the semiconductor substrate 100 with the first hard mask pattern HP1 as an etching mask to form the second trench TR2.

The first upper insulating layer 171 and the second upper insulating layer 172 may be formed by the etching process. A portion of the bottom surface of the upper insulating layer 170 may be recessed toward the top surface of the upper insulation layer 170 by the second trench TR2. The portion of the bottom surface of the upper insulating layer 170 may be recessed toward the data storage pattern DSP.

The upper insulating layer 170 exposed by the second trench TR2 may be referred to as the first upper insulating layer 171. The first upper insulating layer 171 may include a bottom surface 171L recessed toward the top surface 171U of the first upper insulating layer 171. The bottom surface 171L of the first upper insulating layer 171 may be exposed by the second trench TR2. The length 171D of the first upper insulating layer in the third direction D3 may decrease as it approaches the central portion of the first upper insulation layer 171. The length 171D of the first upper insulating layer 171 in the third direction D3 may decrease as it becomes farther from the storage node contact BC in the first direction D1. The length 171D of the first upper insulating layer 171 in the third direction D3 may be, for example, smaller than the length BC_D of the storage node contact BC in the third direction D3.

The bottom surface of the upper insulating layer 170 protected by the lower back gate capping pattern BGP1, the back gate insulating pattern 113, and the first hard mask pattern HP1 may not be recessed. The upper insulating layer 170 having the bottom surface that is not recessed may be referred to as a second upper insulating layer 172. The length 172D of the second upper insulating layer 172 in the third direction D3 may be greater than the length 171D of the first upper insulating layer 171 in the third direction D3. The length 172D of the second upper insulating layer 172 in the third direction D3 may be greater than the minimum length of the length 171D of the first upper insulating layer 171 in the third direction D3.

According to implementations of the present disclosure, the semiconductor pattern SP may be formed after the substrate is flipped. The length SP_D of each of a plurality of the semiconductor patterns SP in the third direction D3 may be substantially the same. The length SP_D of each of the semiconductor patterns SP in the third direction D3 is uniform, and uniformity of levels of the top surfaces of the semiconductor patterns SP may be improved. Thus, a process for manufacturing the semiconductor device with improved reliability may be provided.

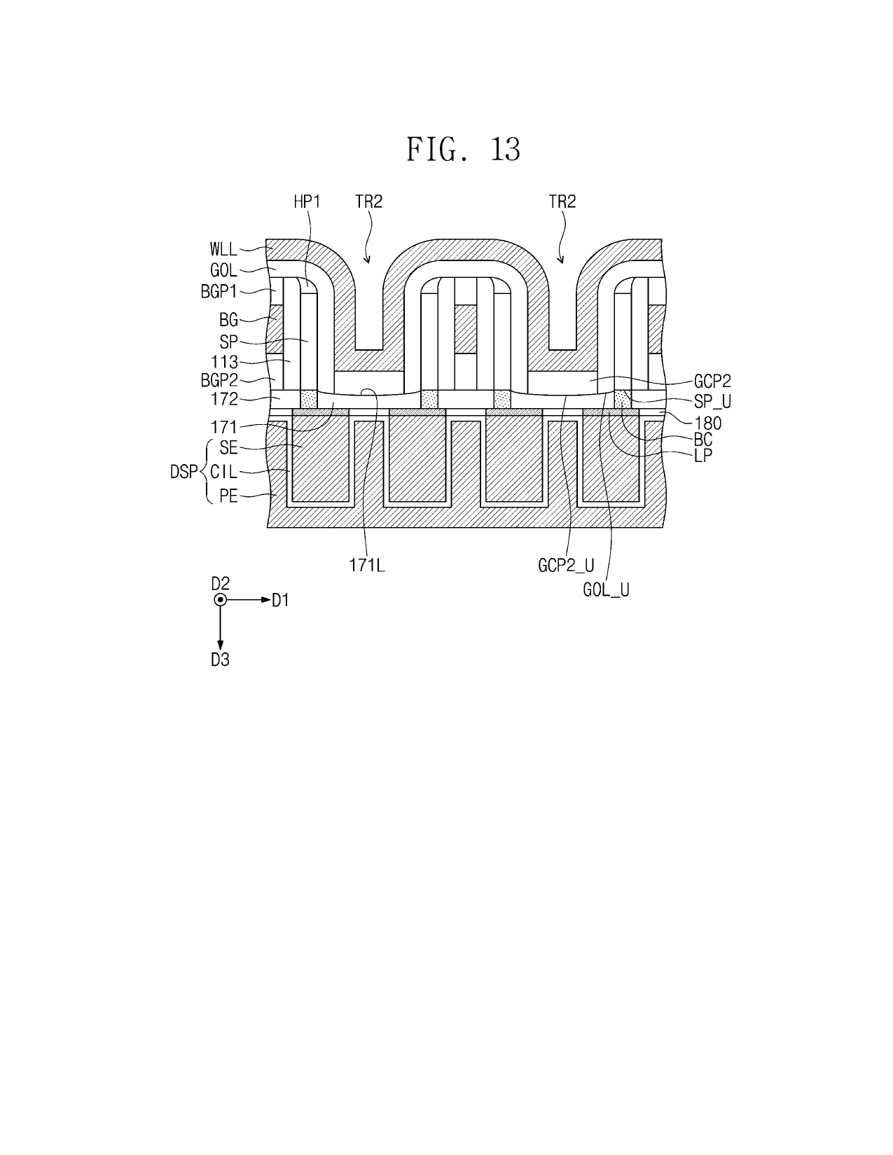

Referring to FIGS. 4 and 13, a gate insulating layer GOL may be formed. The gate insulating layer GOL may cover a bottom surface of the lower back gate capping pattern BGP1, a bottom surface of a back gate insulating pattern 113, and a bottom surface of first hard mask pattern HP1. The gate insulating layer GOL may cover the side surface of the semiconductor pattern SP.

A top surface GOL_U of the gate insulating layer GOL may be formed along a profile of a bottom surface of the first upper insulating layer 171. The top surface GOL_U of the gate insulating layer GOL may be positioned at a higher level than the top surface SP_U of the semiconductor pattern SP.

Forming the gate insulating layer GOL may include, for example, forming a gate insulating layer that fills a portion of the second trench TR2, and removing a portion of the gate insulating layer to expose the bottom surface of the first upper insulating layer 171. The gate insulating layer GOL may be etched by, for example, an anisotropic etching process.

The upper gate capping pattern GCP2 may be formed. The top surface of the upper gate capping pattern GCP2 may be formed along a profile of the bottom surface 171L of the first upper insulating layer 171. The top surface GCP2_U of the upper gate capping pattern GCP2 may be located at a higher level than the top surface SP_U of the semiconductor pattern SP. Forming the upper gate capping pattern GCP2 may include, for example, forming an upper capping insulating layer filling a portion of the second trench TR2, and recessing a portion of the upper capping layer.

A word line layer WLL may be formed on the upper gate capping pattern GCP2 and the gate insulating layer GOL. The word line layer WLL may fill a portion of the second trench TR2.

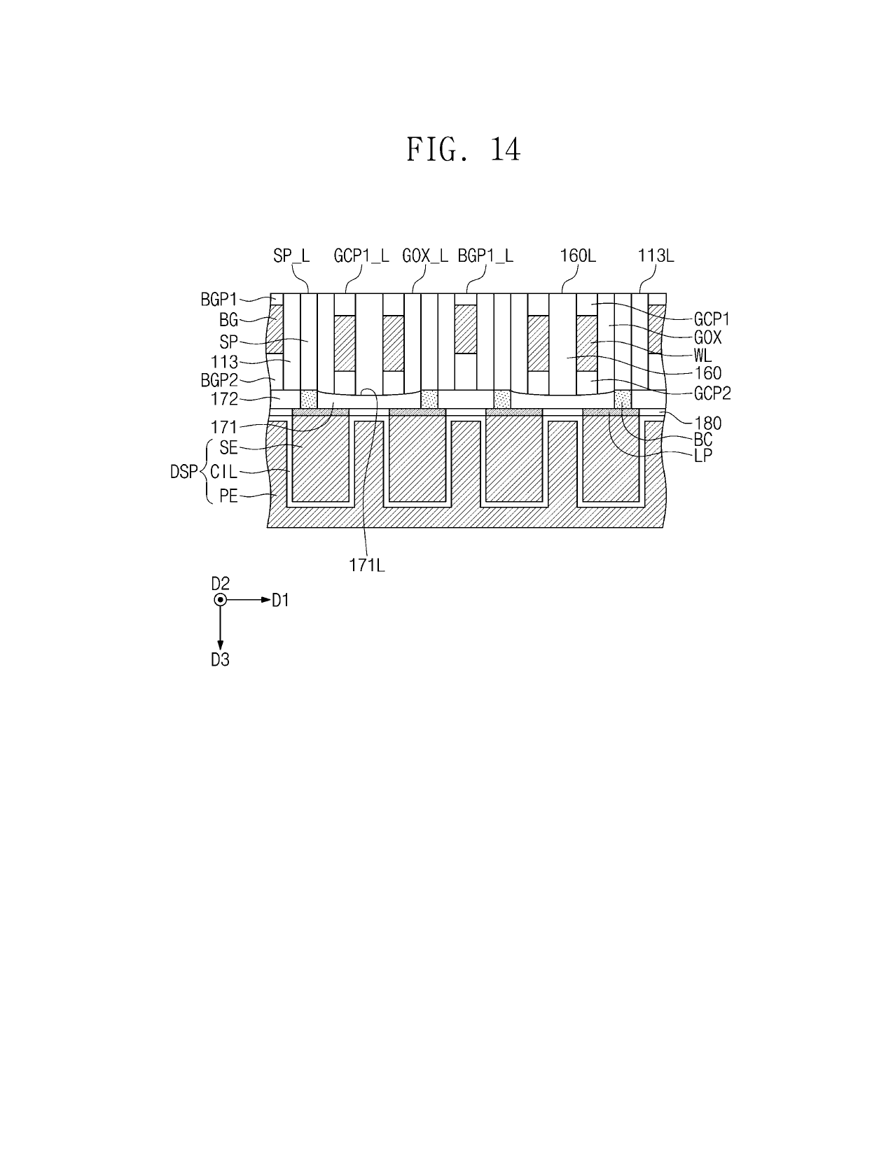

Referring to FIGS. 4 and 14, the word line WL may be formed adjacent to the semiconductor pattern SP. Forming the word line WL may include, for example, recessing the word line layer WLL.

The lower gate capping pattern GCP1 may be formed to fill the remainder of the second trench TR2. Forming the lower gate capping pattern GCP1 may include, for example, forming a lower gate capping layer that fills the remainder of the second trench TR2.

The isolation insulating pattern 160 may be formed in the second trench TR2. The top surface of the isolation insulating pattern 160 may be formed along a profile of the bottom surface 171L of the first upper insulating layer 171. The isolation insulating pattern 160 may be formed to penetrate the lower gate capping pattern GCP1, the word line WL, and the upper gate capping pattern GCP2, and may extend in the second direction D2.

A planarization process may proceed until a bottom surface SP_L of the semiconductor pattern SP is exposed. Due to the planarization process, the first hard mask pattern HP1 may be removed. Due to the planarization process, part of the gate insulating layer may be removed and form the gate insulating pattern GOX.

Due to the planarization process, the bottom surface BGP1_L of the lower back gate capping pattern BGP1, the bottom surface 113L of the back gate insulating pattern 113, the bottom surface SP_L of the semiconductor pattern SP, the bottom surface GOX_L of the gate insulating pattern GOX, the bottom surface GCP1_L of the lower gate capping pattern GCP1, and the bottom surface 160L of the isolation insulating pattern 160 may be exposed and may be coplanar with each other.

Referring again to FIGS. 4 to 6, the bit line contact DC may be formed on the semiconductor pattern SP. The bit line BL may be formed on the bit line contact DC. The lower insulating layer LIL may be formed to cover the bit line contact DC and the bit line BL. The lower insulating layer LIL may be formed at various times regardless of before and after formation of the bit line contact DC and the bit line BL.

According to some implementations of the present disclosure, the semiconductor patterns SP may be formed after the substrate is flipped. The length SP_D of each of the semiconductor patterns SP in the third direction D3 may be substantially the same. The length SP_D of each of the semiconductor patterns SP in the third direction D3 is uniform, and uniformity of levels of the top surfaces of the semiconductor patterns SP may be improved. Therefore, the semiconductor device with improved reliability may be provided.

Furthermore, a bulk silicon substrate (e.g., a single crystal silicon substrate) may be used instead of a Silicon On Insulator (SOI) substrate to fabricate a semiconductor device. Therefore, manufacturing cost of a semiconductor device may be reduced.

According to some implementations of the present disclosure, a manufacturing a semiconductor device may comprise forming a first trench in a substrate; forming a back gate insulating pattern and a back gate electrode extending in a second direction in the first trench; forming an upper insulating layer on the back gate insulating pattern and the back gate electrode; forming a storage node contact through the upper insulating layer; flipping the substrate to expose a lower surface of the back gate insulating pattern; patterning the substrate to form a semiconductor pattern; forming a word line adjacent to the semiconductor pattern and extending in the second direction; and forming a bit line extending in a first direction intersecting the second direction, wherein a portion of a bottom surface of the upper insulating layer may be recessed toward the upper surface of the upper insulation layer.

According to some implementations of the present disclosure, the patterning the semiconductor substrate to form the semiconductor pattern may comprise forming a first hard mask pattern extending in the second direction on a side surface of the back gate insulating pattern; and forming a second hard mask pattern extending in the first direction on the substrate.

According to some implementations of the present disclosure, the forming the first hard mask pattern may be an atomic layer deposition method.

According to some implementations of the present disclosure, the manufacturing a semiconductor device may further comprise etching the substrate to expose a side surface of the back gate insulating pattern before the patterning the substrate to form the semiconductor pattern.

According to some implementations of the present disclosure, the substrate may be a single crystal silicon substrate.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the implementations have been described above with reference to the accompanying drawings, it will be understood by those skilled in the art that the present disclosure may be embodied in other specific forms without altering the technical spirit or essential features thereof. It is, therefore, to be understood that the implementations described above are illustrative in all respects and not restrictive.

What is claimed is:

1. A semiconductor device comprising:
a bit line extending in a first direction;
a word line extending in a second direction intersecting the first direction;
a semiconductor pattern adjacent to the word line;
a back gate electrode spaced apart from the word line, the semiconductor pattern being interposed between the back gate electrode and the word line; and
an isolation insulating pattern spaced apart from the semiconductor pattern, the word line being interposed between the isolation insulating pattern and the semiconductor pattern,
wherein a length of the isolation insulating pattern in a third direction is greater than a length of the semiconductor pattern in the third direction, the third direction being perpendicular to the first direction and the second direction.

2. The semiconductor device of claim 1, comprising a gate insulating pattern interposed between the word line and the semiconductor pattern, and
wherein a top surface of the gate insulating pattern is at a higher level than a level of the semiconductor pattern.

3. The semiconductor device of claim 2, wherein a length of the gate insulating pattern in the third direction is greater than a length of the semiconductor pattern in the third direction.

4. The semiconductor device of claim 1, comprising an upper gate capping pattern on the word line, and
wherein a top surface of the upper gate capping pattern is at a higher level than a level of the semiconductor pattern.

5. The semiconductor device of claim 1, comprising a first upper insulating layer on the word line; and
a data storage pattern on the first upper insulating layer,
wherein a bottom surface of the first upper insulating layer is recessed toward the data storage pattern.

6. The semiconductor device of claim 5, comprising a second upper insulating layer on the back gate electrode, and
wherein a bottom surface of the second upper insulating layer is at a lower level than a level of the first upper insulating layer.

7. The semiconductor device of claim 6, comprising a storage node contact on the semiconductor pattern, and
wherein the first upper insulating layer and the second upper insulating layer cover the storage node contact.

8. The semiconductor device of claim 7, wherein the first upper insulating layer and the second upper insulating layer comprise silicon nitride.

9. The semiconductor device of claim 1, comprising a back gate insulating pattern interposed between the back gate electrode and the semiconductor pattern, and
wherein a top surface of the back gate insulating pattern is at a lower level than a level of the isolation insulating pattern.

10. The semiconductor device of claim 1, comprising an upper back gate capping pattern on the back gate electrode,
wherein a top surface of the upper back gate capping pattern is at a lower level than a level of the isolation insulating pattern.

11. The semiconductor device of claim 10, wherein a top surface of the upper back gate capping pattern and a top surface of the semiconductor pattern are coplanar with each other.

12. The semiconductor device of claim 1, wherein a top surface of the isolation insulating pattern is at a higher level than a level of the semiconductor pattern.

13. A semiconductor device, comprising:
a bit line extending in a first direction;
a word line extending in a second direction intersecting the first direction;
a semiconductor pattern adjacent to the word line;
a back gate electrode spaced apart from the word line, he semiconductor pattern being interposed between the back gate electrode and the word line; and
a first upper insulating layer on the word line,
wherein a bottom surface of the first upper insulating layer is recessed toward a top surface of the first upper insulating layer.

14. The semiconductor device of claim 13, comprising a second upper insulating layer on the back gate electrode; and
a storage node contact on the semiconductor pattern,
wherein the first upper insulating layer and the second upper insulating layer cover the storage node contact,
wherein a minimum length in a third direction of the first upper insulating layer is smaller than a length in the third direction of the second upper insulating layer, and
the third direction being perpendicular to the first direction and the second direction.

15. The semiconductor device of claim 14, wherein a length of the storage node contact in the third direction is greater than a minimum length of the first upper insulating layer in the third direction.

16. The semiconductor device of claim 13, comprising a gate insulating pattern interposed between the word line and the semiconductor pattern; and
an isolation insulating pattern spaced apart from the semiconductor pattern with the word line interposed therebetween,
wherein the first upper insulating layer is on the gate insulating pattern, the isolation insulating pattern, and the word line,
wherein a length of the first upper insulating layer in a third direction decreases as it gets closer to the isolation insulating pattern, and
the third direction being perpendicular to the first direction and the second direction.

17. The semiconductor device of claim 16, wherein a length of the gate insulating pattern in the third direction is smaller than a length of the isolation insulating pattern in the third direction.

18. A semiconductor device, comprising:
a bit line extending in a first direction;
a word line extending in a second direction intersecting the first direction;
a semiconductor pattern adjacent to the word line;
a gate insulating pattern interposed between the word line and the semiconductor pattern;
a back gate electrode spaced apart from the word line and the semiconductor pattern;
an isolation insulating pattern spaced apart from the semiconductor pattern, the word line being interposed between the isolation insulating pattern and the semiconductor pattern;
a storage node contact on the semiconductor pattern;
a data storage pattern on the storage node contact; and
a landing pad interposed between the data storage pattern and the storage node contact,
wherein a top surface of the isolation insulating pattern is at a higher level than a level of the semiconductor pattern.

19. The semiconductor device of claim 18, comprising a first upper insulating layer on the word line; and
a second upper insulating layer on the back gate electrode,
wherein the first upper insulating layer and the second upper insulating layer cover the storage node contact, and
a bottom surface of the first upper insulating layer is recessed toward the data storage pattern.

20. The semiconductor device of claim 18, wherein a length of the isolation insulating pattern in a third direction is greater than a length of the semiconductor pattern in the third direction,
the third direction being perpendicular to the first direction and the second direction.
